(19) United States
(12) Patent Application Publication
(10) Pub. No.: US 2025/0087513 A1
(43) Pub. Date: Mar. 13, 2025

(54) TRANSFER APPARATUS AND SUBSTRATE PROCESSING APPARATUS

(71) Applicant: EBARA CORPORATION, Tokyo (JP)

(72) Inventors: Masaya SEKI, Tokyo (JP); Nobuya YAMADA, Tokyo (JP); Masaki TOMITA, Tokyo (JP)

(21) Appl. No.: 18/572,138

(22) PCT Filed: Dec. 7, 2022
(86) PCT No.: PCT/JP2022/045030

§ 371 Date: Dec. 19, 2023

(51) Int. Cl. H01L 21/677; H01L 21/67; H01L 21/687

(52) U.S. Cl. CPC H01L 21/67715; H01L 21/67167; H01L 21/67712; H01L 21/68707

(57) ABSTRACT

To improve a transfer rate of substrates and suppress particles from adhering to the surfaces to be processed of the substrates.

A transfer apparatus configured to transfer a substrate in an elevating direction and a traveling direction perpendicular to the elevating direction includes an attachment member 710-1. The attachment member 710-1 is fixed to a side surface of a module frame 402A for installing a plating module including a substrate loading/unloading port 404-1 to 404-8. The attachment member 710-1 includes a plurality of traveling rails 714-1 to 714-3 extending in a traveling direction disposed on both sides of the substrate loading/unloading port 404-1 to 404-8 in the elevating direction. The transfer apparatus includes an elevating rail 716 extending in the elevating direction across the plurality of traveling rails 714-1 to 714-3 and being movable along the plurality of traveling rails 714-1 to 714-3, and a transfer robot 718 configured to be movable vertically along the elevating rail 716 and including a hand for holding a substrate.

### TECHNICAL FIELD

The present application relates to a transfer apparatus and a substrate processing apparatus.

### BACKGROUND ART

A substrate processing apparatus for performing various processes on a surface to be processed of a substrate (for example, a semiconductor wafer) is known. The substrate processing apparatus is, for example, a substrate electroplating apparatus for forming a conductive film on a surface to be plated of a substrate, or a chemical mechanical polishing (CMP) device for polishing and planarizing the surface to be polished of the substrate.

The substrate processing apparatus includes a transfer apparatus for transferring the substrate inside the apparatus. The transfer apparatus disclosed in PTL 1 includes a horizontal motion assembly extending horizontally on a floor surface of the substrate processing apparatus, a vertical motion assembly vertically installed on the horizontal motion assembly, and a robot assembly installed on the vertical motion assembly. The transfer apparatus is configured to move the robot assembly in an elevating direction along the vertical motion assembly and move the vertical motion assembly horizontally along the horizontal motion assembly so as to transfer the substrate held by the robot assembly.

Furthermore, PTL 1 discloses that the horizontal motion assembly is provided also at the top of the vertical motion assembly, thereby increasing a stiffness of the transfer apparatus and increasing the horizontal motion velocity of the substrate.

### CITATION LIST

### Patent Literature

PTL 1: U.S. Pat. No. 8,066,466 B2

### SUMMARY OF INVENTION

### Technical Problem

However, in the transfer apparatus disclosed in PTL 1, it is not considered to improve the transfer rate of the substrates and suppress particles from adhering to the surfaces to be processed of the substrates.

That is, in the substrate processing apparatus, it is known to suppress particles from adhering to the surfaces to be processed by providing a fan filter module in the upper portion of a substrate transferring path and supplying clean air to the surfaces to be processed of the substrates. In this regard, as in the transfer apparatus disclosed in PTL 1, when the horizontal motion assembly is installed directly above the substrate held by the transfer apparatus, it is difficult to supply clean air to the surface to be processed, and as a result, there is a possibility that particles adhere to the surface to be processed.

Therefore, the object of the present application is to improve the transfer rate of the substrates and to suppress particles from adhering to the surfaces to be processed of the substrates.

### Solution to Problem

According to one embodiment, there is disclosed a transfer apparatus configured to transfer a substrate in an elevating direction and a traveling direction perpendicular to the elevating direction. The transfer apparatus includes an attachment member, an elevating rail, and a transfer robot. The attachment member is fixed to a side surface of a module frame for installing a processing module including a substrate loading/unloading port. The attachment member includes a plurality of traveling rails extending in a traveling direction. The plurality of traveling rails are disposed on both sides of the substrate loading/unloading port in the elevating direction. The elevating rail extends in the elevating direction across the plurality of traveling rails and is movable along the plurality of traveling rails. The transfer robot is configured to be movable vertically along the elevating rail and including a hand for holding a substrate.

### BRIEF DESCRIPTION OF DRAWINGS

FIG. 1 is a perspective view illustrating an overall configuration of a plating apparatus according to one embodiment.

FIG. 2A is a plan view illustrating the overall configuration of the plating apparatus according to one embodiment.

FIG. 2B is a cross-sectional view of the B-B line of FIG. 2A.

FIG. 2C is a cross-sectional view of the C-C line of FIG. 2B.

FIG. 3 is a perspective view schematically illustrating a configuration of a part of a module frame according to one embodiment.

FIG. 4A is a plan view illustrating an overall configuration of a plating apparatus according to one embodiment.

FIG. 4B is a cross-sectional view of the B-B line of FIG. 4A.

FIG. 4C is a cross-sectional view of the C-C line of FIG. 4B.

FIG. 5 is a perspective view schematically illustrating a configuration of a transfer apparatus according to one embodiment.

FIG. 6A is a plan view illustrating the overall configuration of the plating apparatus according to one embodiment.

FIG. 6B is a cross-sectional view of the B-B line of FIG. 6A.

FIG. 6C is a cross-sectional view of the C-C line of FIG. 6B.

FIG. 7A is a plan view illustrating the overall configuration of the plating apparatus according to one embodiment.

FIG. 7B is a cross-sectional view of the B-B line of FIG. 7A.

FIG. 7C is a cross-sectional view of the C-C line of FIG. 7B.

FIG. 8A is a plan view illustrating the overall configuration of the plating apparatus according to one embodiment.

FIG. 8B is a cross-sectional view of the B-B line of FIG. 8A.

FIG. 8C is a cross-sectional view of the C-C line of FIG. 8B.

### DESCRIPTION OF EMBODIMENTS

The following describes embodiments of the present invention with reference to the drawings. In the drawings that will be described below, components that are identical or correspond to one another will be denoted by the same reference numerals, and overlapped descriptions will be omitted. In the following embodiment, a plating apparatus is exemplified as a substrate processing apparatus, but the present invention is not limited thereto, and a transfer apparatus of this embodiment can be applied to a chemical mechanical polishing (CMP) apparatus for polishing and planarizing a surface to be polished of a substrate.

### <Overall Configuration of Plating Apparatus>

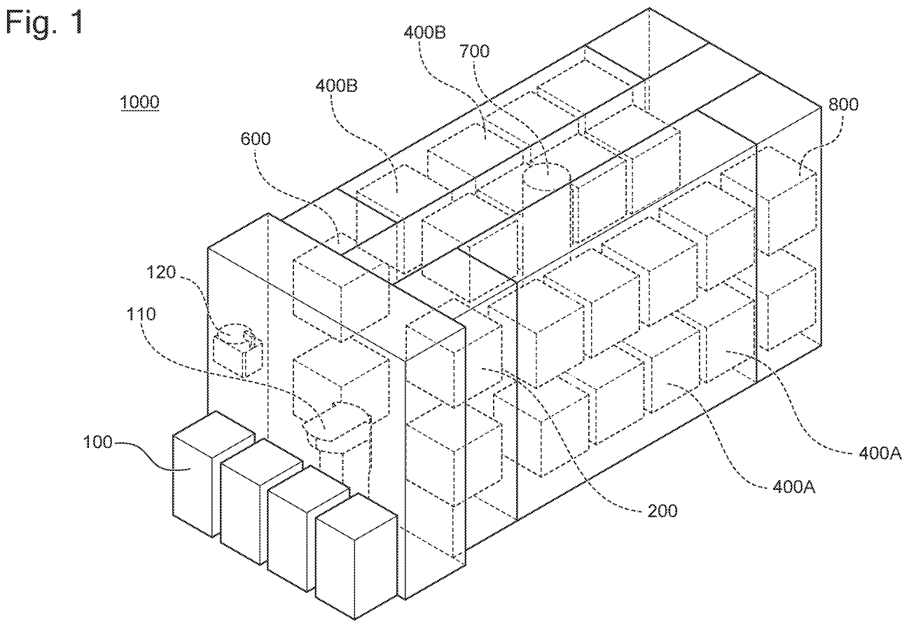

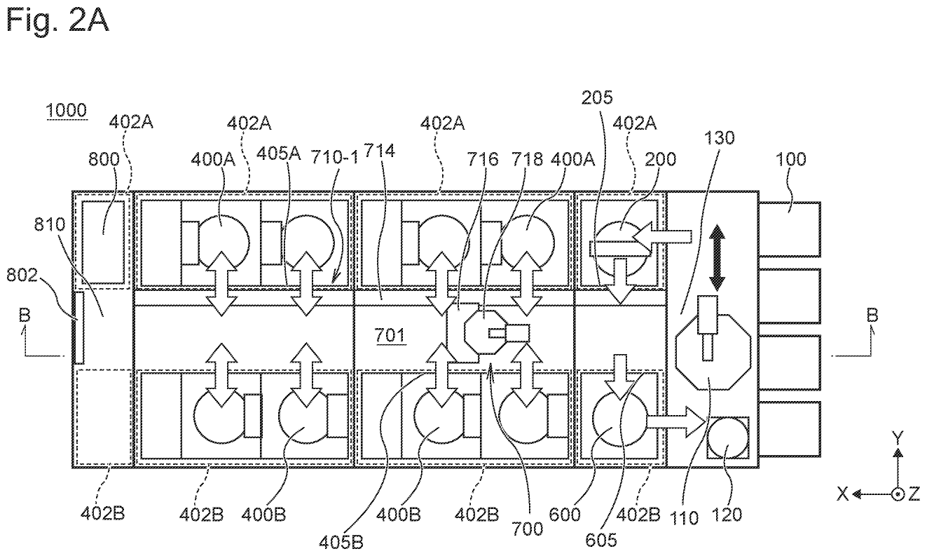

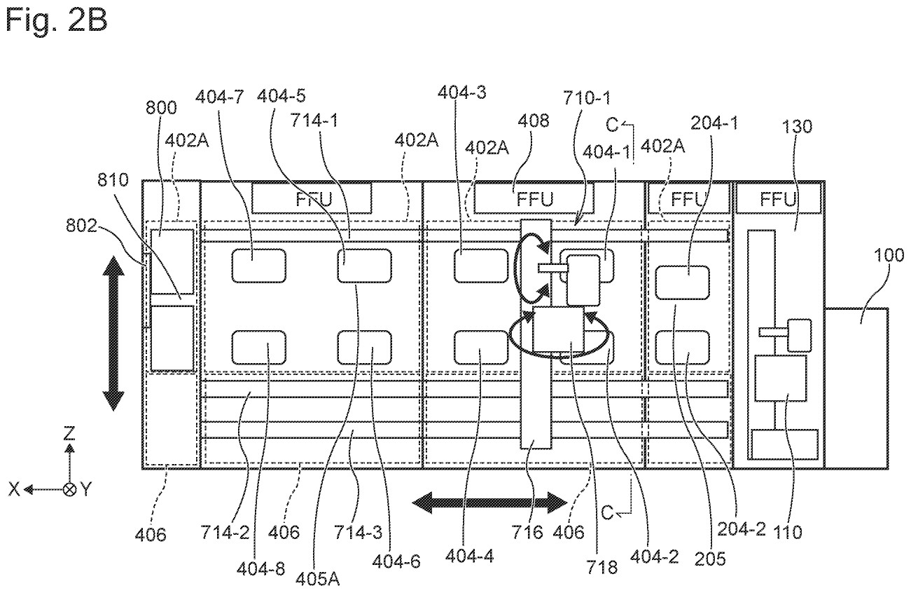

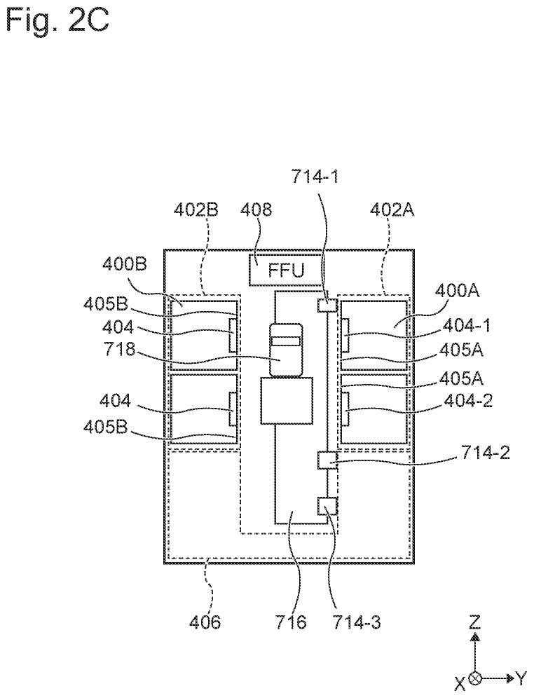

FIG. 1 is a perspective view illustrating an overall configuration of a plating apparatus of this embodiment. FIG. 2A is a plan view illustrating the overall configuration of the plating apparatus of this embodiment. As illustrated in FIGS. 1 and 2A, a plating apparatus 1000 includes load ports 100, a transfer robot 110, an aligner 120, pre-wet modules 200, plating modules 400, spin rinse dryers 600, a transfer apparatus 700, and a control module 800.

The load port 100 is a module for loading a substrate housed in a cassette, such as a FOUP, (not illustrated) to the plating apparatus 1000 and unloading the substrate from the plating apparatus 1000 to the cassette. While the four load ports 100 are disposed in the horizontal direction in this embodiment, the number and arrangement of the load ports 100 are arbitrary. The transfer robot (a dry robot) 110 is a robot for transferring the substrate. The transfer robot 110 is configured to grip or release the substrate between the load ports 100, the aligner 120, the pre-wet module 200, and the spin rinse dryer 600.

The aligner 120 is a module for adjusting a position of an orientation flat, a notch, and the like of the substrate in a predetermined direction. While the one aligner 120 is disposed in this embodiment, the number and arrangement of the aligners 120 are arbitrary. The pre-wet module 200 wets a surface to be plated of the substrate before a plating process with a process liquid, such as pure water or deaerated water, to replace air inside a pattern formed on the surface of the substrate with the process liquid. The pre-wet module 200 is configured to perform a pre-wet process to facilitate supplying the plating solution to the inside of the pattern by replacing the process liquid inside the pattern with a plating solution during plating. While the two pre-wet modules 200 are disposed side by side in the vertical direction in this embodiment, the number and arrangement of the pre-wet modules 200 are arbitrary.

The plating module 400 is a module for applying a plating process on the substrate. In this embodiment, the plating module 400 includes eight plating modules 400A disposed on one side across a travel path of the transfer apparatus 700 and eight plating modules 400B disposed on the opposite side across the travel path of the transfer apparatus 700. In this embodiment, a total of 16 plating modules 400 are provided, but the number and arrangements of the plating modules 400 are arbitrary.

The spin rinse dryer 600 is one configuration of a drying module for rotating and drying the substrate at high speed after the plating process. While the two spin rinse dryers are disposed side by side the vertical direction in this embodiment, the number and arrangement of the spin rinse dryers are arbitrary. The transfer apparatus 700 is a device for transferring the substrate between the plurality of modules in the plating apparatus 1000. The control module 800 is configured to control the plurality of modules in the plating apparatus 1000 and can be configured of, for example, a general computer including input/output interfaces with an operator or a dedicated computer.

An example of a sequence of the plating processes by the plating apparatus 1000 will be described. First, the substrate housed in the cassette is loaded on the load port 100. Subsequently, the transfer robot 110 grips the substrate from the cassette at the load port 100 and transfers the substrate to the aligner 120. The aligner 120 adjusts the position of the orientation flat, the notch, or the like of the substrate in the predetermined direction. The transfer robot 110 grips or releases the substrate whose direction is adjusted with the aligner 120 to the pre-wet module 200.

The pre-wet module 200 performs the pre-wet process on the substrate. The transfer apparatus 700 transfers the substrate on which the pre-wet process has been performed to the plating module 400. The plating module 400 performs the plating process on the substrate.

The transfer apparatus 700 transfers the plated substrate to another plating module 400 for a composite plating process or to the spin rinse dryer 600. The spin rinse dryer 600 performs the drying process on the substrate. The transfer robot 110 receives the substrate from the spin rinse dryer 600 and transfers the substrate on which the drying process has been performed to the cassette at the load port 100. Finally, the cassette housing the substrate is unloaded from the load port 100.

Next, details of the plating apparatus 1000 will be described. FIG. 2B is a cross-sectional view of the B-B line of FIG. 2A. FIG. 2C is a cross-sectional view of the C-C line of FIG. 2B. In FIG. 2A to FIG. 2C, for convenience, the transfer apparatus 700 has a traveling direction in a X direction, the transfer robot 110 has a traveling direction in a Y direction, and a vertical direction is in a Z direction.

In FIG. 2A to FIG. 2C, the pre-wet module 200 and the plating module 400A, which are exemplary of the first processing module, are installed in first module frames 402A indicated by the dashed lines. The control module 800 is also installed in the first module frame 402A indicated by the dashed line. In addition, the plating module 400B and the spin rinse dryer 600, which are exemplary of the second processing module, are installed in second module frames 402B indicated by the dashed lines. Note that the first module frame 402A and the second module frame 402B are configured to include a plurality of module frames disposed adjacently as illustrated in FIG. 2A and FIG. 2B indicated by the dashed lines. While in this embodiment the two control modules 800 are installed in the first module frame 402A, this embodiment is not limited thereto, and the control module 800 may be installed in the second module frame 402B.

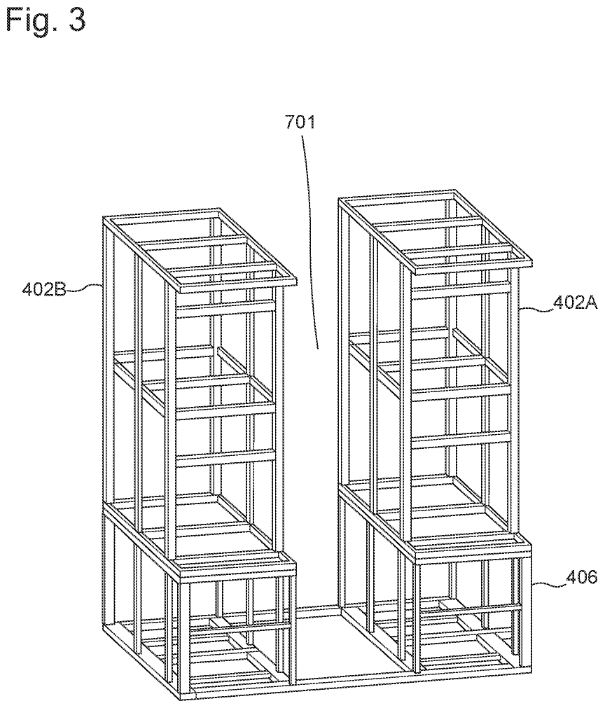

FIG. 3 is a perspective view schematically illustrating a configuration of a part of a module frame according to one embodiment. FIG. 3 illustrates, as a part of the module frame, the first module frame 402A in which four of the plating modules 400A are installed, the second module frame 402B in which four of the plating modules 400B are installed, and a base frame 406 disposed in the lower part thereof. As illustrated in FIG. 3, the first module frame 402A and the second module frame 402B are racks of a framework for installing the plating modules 400 and the like. The first module frames 402A and the second module frames 402B are disposed on the respective base frames 406 for installing a plating solution reservoir for use in the plating module 400, a pump for pumping the plating solution, and the like.

Each of the plating modules 400A has a first side surface 405A on which a substrate loading/unloading port 404 (404-1 to 404-8) for gripping or releasing of the substrate with the transfer apparatus 700 are formed. Further, each of the pre-wet modules 200 has a first side surface 205 on which a substrate loading/unloading port 204 (204-1 to 204-2) for gripping or releasing of the substrate with the transfer apparatus 700 is formed. On the other hand, each of the plating modules 400B has a second side surface 405B on which the substrate loading/unloading port 404 for gripping or releasing of the substrate with the transfer apparatus 700 is formed. Further, each of the spin rinse dryers 600 has a second side surface 605 on which a substrate loading/unloading port 604 for gripping or releasing of the substrate with the transfer apparatus 700 is formed.

The first module frame 402A and the second module frame 402B are disposed to be spaced apart from each other such that the first side surfaces 405A, 205 and the second side surfaces 405B, 605 face each other. Accordingly, a substrate transfer space 701 is formed between the first side surfaces 405A, 205 and the second side surfaces 405B, 605. The transfer apparatus 700 is disposed in the substrate transfer space 701.

### <Configuration of Transfer Apparatus>

Next, details of the transfer apparatus 700 will be described. As illustrated in FIG. 2, the transfer apparatus 700 includes an attachment member 710-1 fixed to a side surface of the first module frame 402A (a side surface on which the substrate loading/unloading port 204 and the substrate loading/unloading port 404 are disposed), an elevating rail 716 attached to the attachment member 710-1, and a transfer robot 718 including a hand for holding the substrate.

The attachment member 710-1 is a member for attaching the elevating rail 716 and the transfer robot 718 to the side surface of the first module frame 402A. The attachment member 710-1 includes a plurality (three in this embodiment) of traveling rails 714 (714-1 to 714-3) fixed to the side surfaces of the first module frames 402A and the base frames 406 and extending in the traveling direction (X direction). The traveling rails 714-1, 714-2 are disposed on both sides of the substrate loading/unloading ports 204-1, 204-2 and the substrate loading/unloading ports 404-1 to 404-8 in the Z direction. The traveling rail 714-3 is disposed below the traveling rail 714-2. While in this embodiment the three traveling rails 714 are provided to increase the stiffness of the attachment member 710-1, this embodiment is not limited thereto, and the two traveling rails (the traveling rails 714-1, 714-2 or the traveling rails 714-1, 714-3) may be provided. While in this embodiment the traveling rails 714-2, 714-3 are fixed to the side surface of the base frame 406, this embodiment is not limited thereto, and the traveling rails 714-2, 714-3 may be fixed to the side surface of the first module frame 402A.

The elevating rail 716 extends in an elevating direction across the side surfaces of the plurality of traveling rails 714 and is configured to be movable along the side surfaces of the plurality of traveling rails 714. Specifically, the elevating rail 716 is attached to the traveling rail 714 via a slider 715 movable along the traveling rails 714. The elevating rails 716 are configured to move along the traveling rails 714 by a drive member (for example, a motor), which is not illustrated.

The transfer robot 718 is a member that rotates vertically along the elevating rail 716. Specifically, the transfer robot 718 is configured to be movable vertically along the elevating rail 716 by a drive member (for example, a motor), which is not illustrated. The transfer apparatus 700 can transfer the substrate in the X and Z directions by moving the elevating rail 716 in the traveling direction and the transfer robot 718 in the elevating direction. Thus, the transfer apparatus 700 can transfer the substrate in front of the substrate loading/unloading port of the processing module as a transfer destination of the substrate.

Further, the transfer robot 718 is configured to be able to rotate the hand about the elevating rail 716 in a horizontal plane. Thus, after the substrate is transferred in front of the substrate loading/unloading port, the transfer robot 718 can transfer the substrate through the attachment member 710-1 into the processing module by rotating the hand. Note that the transfer robot 718 is configured to be capable of reversing the top and bottom of the horizontally held substrate. As a result, the transfer robot 718 can reverse, for example, the plated substrate with the plated surface facing downward and transfer the plated substrate with the plated surface facing upward to the spin rinse dryer 600.

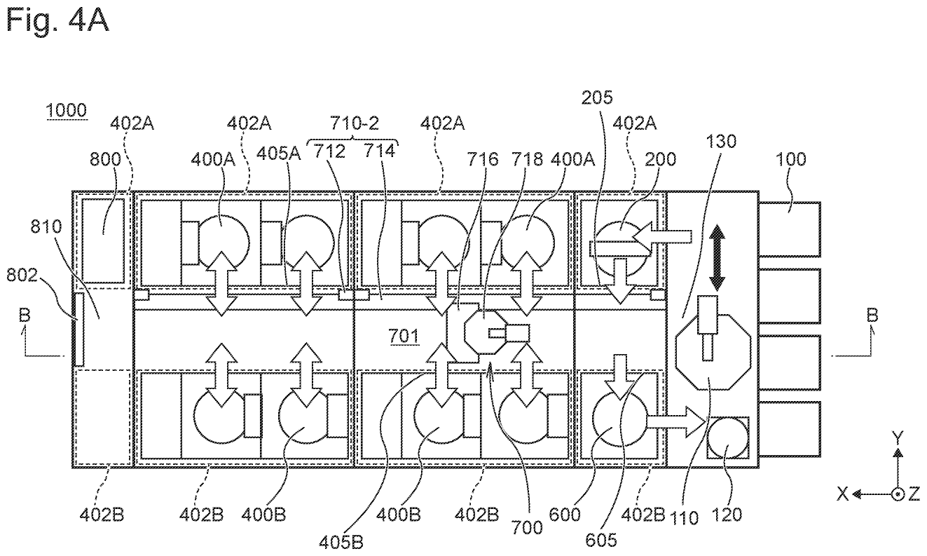

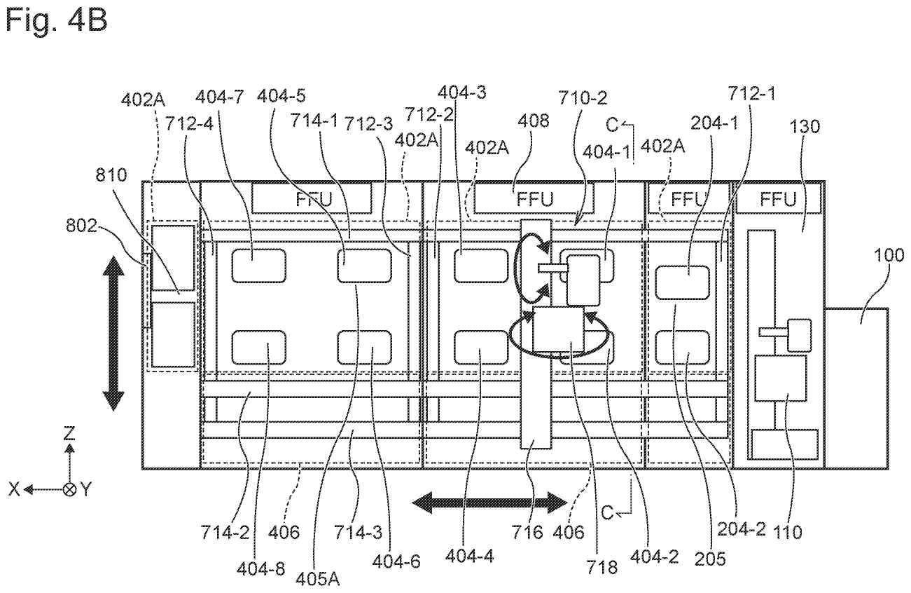

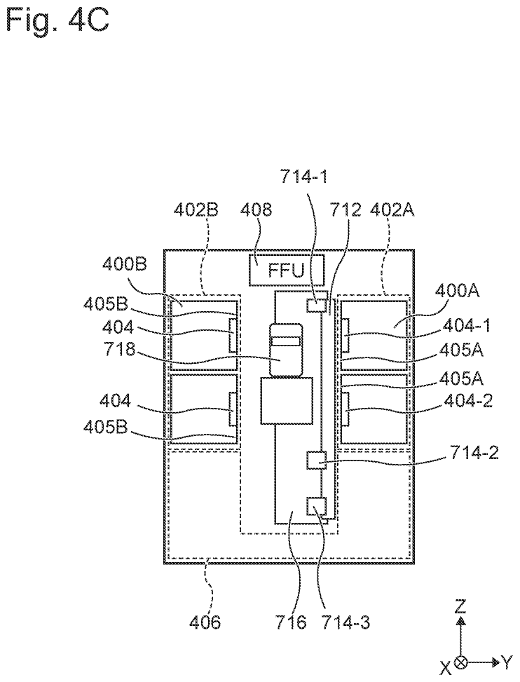

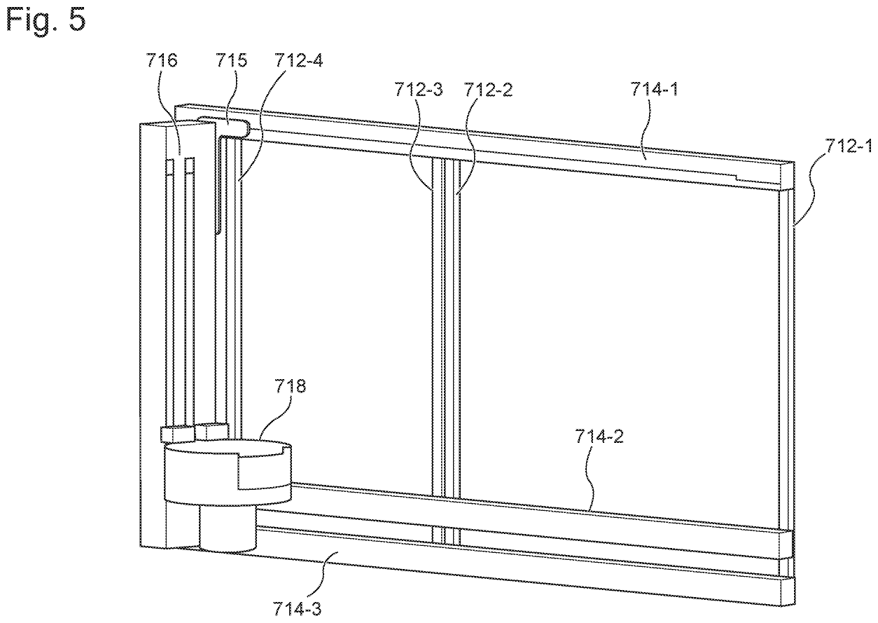

In the embodiment illustrated in FIG. 2, the attachment member 710-1 includes a plurality of traveling rails 714, but the embodiment is not limited thereto. A modification of the transfer apparatus 700 will be described below. FIG. 4A is a plan view illustrating an overall configuration of a plating apparatus according to one embodiment. FIG. 4B is a cross-sectional view of the B-B line of FIG. 4A. FIG. 4C is a cross-sectional view of the C-C line of FIG. 4B. FIG. 5 is a perspective view schematically illustrating a configuration of a transfer apparatus according to one embodiment.

As illustrated in FIG. 4 and FIG. 5, an attachment member 710-2 includes a plurality (four in this embodiment) of fixed rails 712 (712-1 to 712-4) fixed to the side surface of the first module frame 402A and extending in the elevating direction (Z direction). The fixed rails 712-1, 712-2 are disposed on both sides of the substrate loading/unloading ports 204-1, 204-2 and the substrate loading/unloading ports 404-1 to 404-4 in the X direction. The fixed rails 712-3, 712-4 are disposed on both sides of the substrate loading/unloading ports 404-5 to 404-8 in the X direction.

The attachment member 710-2 includes a plurality (three in this embodiment) of traveling rails 714 (714-1 to 714-3) fixed to the plurality of fixed rails 712 and extending in the traveling direction (X direction). The traveling rails 714-1, 714-2 are disposed on both sides of the substrate loading/unloading ports 204-1, 204-2 and the substrate loading/unloading ports 404-1 to 404-8 in the Z direction. The traveling rail 714-3 is disposed below the traveling rail 714-2.

As illustrated in FIG. 4B, the fixed rails 712-1, 712-2 and the traveling rails 714-1, 714-2 are disposed to surround the substrate loading/unloading ports 204-1, 204-2 and the substrate loading/unloading ports 404-1 to 404-4. The fixed rails 712-3, 712-4 and the traveling rails 714-1, 714-2 are disposed to surround the substrate loading/unloading ports 404-5 to 404-8. The traveling rails 714-1 to 714-3 may be dividable between the fixed rails 712-2, 712-3. In this case, the attachment member 710-2 can be divided into a first attachment member surrounding the substrate loading/unloading ports 204-1, 204-2 and the substrate loading/unloading ports 404-1 to 404-4 and a second attachment member surrounding the substrate loading/unloading ports 404-5 to 404-8. As a result, it is possible to easily perform the transfer operation and the mounting operation when the attachment member 710-2 is assembled into the plating apparatus 1000.

As illustrated in FIGS. 2B and 2C, and FIGS. 4B and 4C, the plating apparatus 1000 includes a fan filter device 408 disposed in an upper portion of the substrate transfer space 701. The fan filter device 408 is an exemplary fan module configured to provide a gas to the substrate transfer space 701. Providing the fan filter device 408 allows a downflow of clean air to be formed in the substrate transfer space 701, thus allowing particles or the like in the substrate transfer space 701 to be removed.

According to this embodiment, the stiffnesses of the attachment members 710-1, 710-2 can be increased because the attachment members 710-1, 710-2 are configured to include a plurality of traveling rails 714 that are disposed at intervals in the Z direction across the substrate loading/unloading ports 204, 404. Thus, since the elevating rail 716 can move at high speed in the X direction, the transfer apparatus 700 can improve the transfer rate of the substrate. As a result, the plating apparatus 1000 can improve in throughput.

In addition, according to this embodiment, it is possible to suppress particles from adhering to the surface to be processed (a surface to be plated) of the substrate. That is, the transfer apparatus 700 of this embodiment is fixed to the side surface of the first module frame 402A in a wall-mounted manner via the attachment members 710-1, 710-2, and is configured such that the elevating rail 716 and the transfer robot 718 move along the side surfaces of the attachment members 710-1, 710-2. Therefore, there is no need to provide a member for increasing the stiffness between the fan filter device 408 and the substrate as in the prior art. Therefore, since the clean air can be downflow-supplied from the fan filter device 408 to the surface to be plated of the substrate, it is possible to suppress particles from adhering to the surface to be processed.

Further, as illustrated in FIGS. 2A and 2B and FIGS. 4A and 4B, the transfer robot (a dry robot) 110 is disposed in a first area 130 disposed adjacently to the substrate transfer space 701 in the traveling direction (X direction) of the transfer robot 718. In addition, an access port 802 for accessing the transfer apparatus 700 disposed in the substrate transfer space 701 from outside of the plating apparatus 1000 is formed in a second area 810 disposed on the opposite side of the first area 130 adjacently to the substrate transfer space 701 in the traveling direction (X direction) of the transfer robot 718. By providing the access port 802, the operator can easily perform the maintenance operation of the transfer apparatus 700 via the access port 802 without disassembling the plating apparatus 1000.

In this embodiment, the substrate transfer space 701 is formed to be surrounded by the side surfaces of the pre-wet module 200, the plating modules 400A and 400B, and the spin rinse dryer 600. Therefore, since a housing (frame and side wall) for forming the substrate transfer space 701 need not be provided, the structure of the plating apparatus 1000 can be simplified. In addition, when the substrate transfer space 701 is provided with a housing, the housing for forming the substrate transfer space 701 needs to be manufactured every time the plating modules 400A and 400B or another processing module is resized in the X direction. On the other hand, according to this embodiment, since the housing for forming the substrate transfer space 701 does not need to be manufactured, the size of the processing module in the X direction can be flexibly changed.

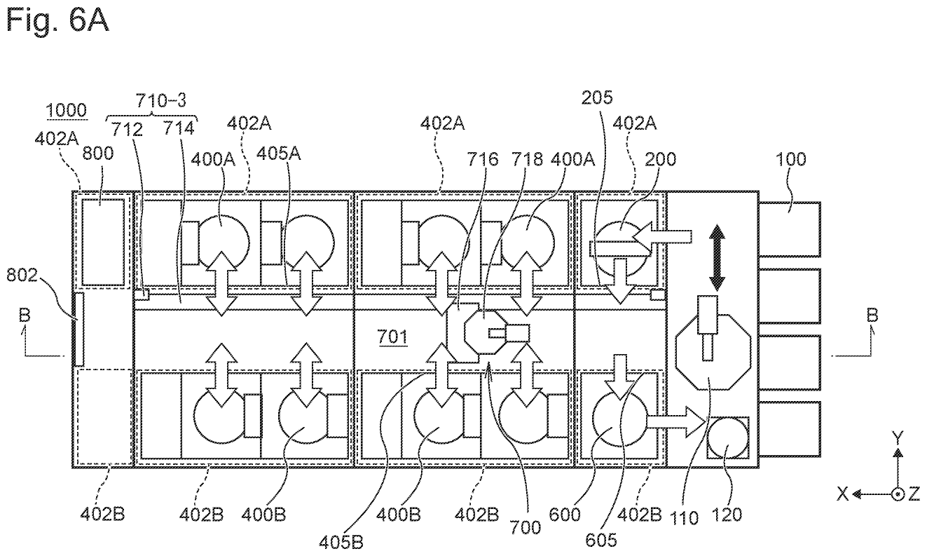

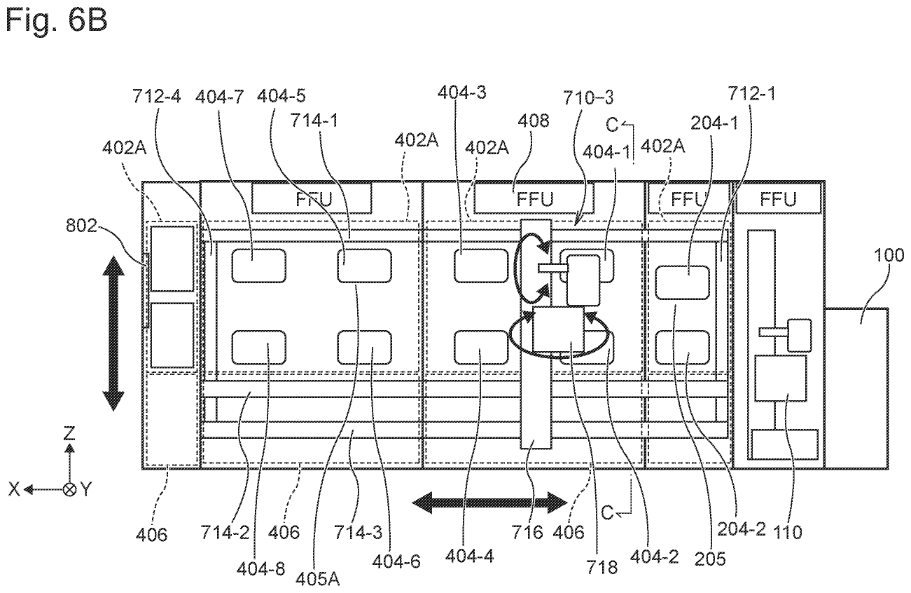

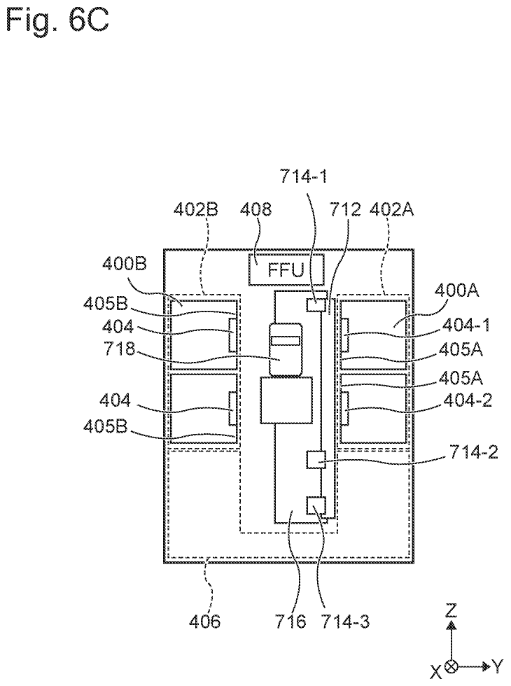

Next, a modification of the plating apparatus 1000 will be described. FIG. 6A is a plan view illustrating an overall configuration of a plating apparatus according to one embodiment. FIG. 6B is a cross-sectional view of the B-B line of FIG. 6A. FIG. 6C is a cross-sectional view of the C-C line of FIG. 6B. Since the plating apparatus 1000 illustrated in FIG. 6 is the same as the plating apparatus 1000 illustrated in FIG. 4 except for the attachment member configuration, the same configuration will not be described.

As illustrated in FIG. 6, the attachment member 710-3 is different from the attachment member 710-2 of FIG. 4 in that the fixed rails 712-2, 712-3 are not provided. Specifically, the attachment member 710-3 includes the fixed rails 712-1, 712-4 and the traveling rails 714-1 to 714-3. According to this embodiment, since the number of members of the attachment member 710-3 can be reduced, the transfer and assembly operations of the attachment member 710-3 can be simplified.

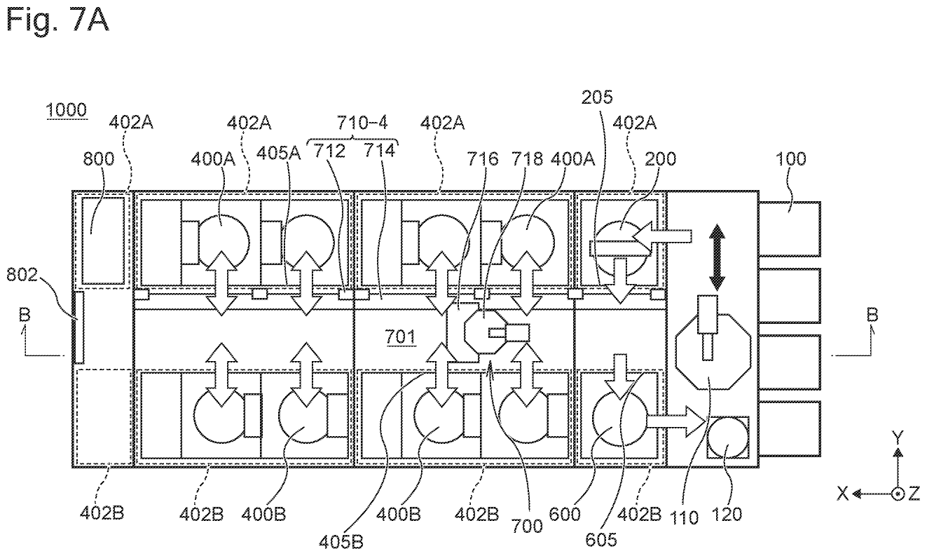

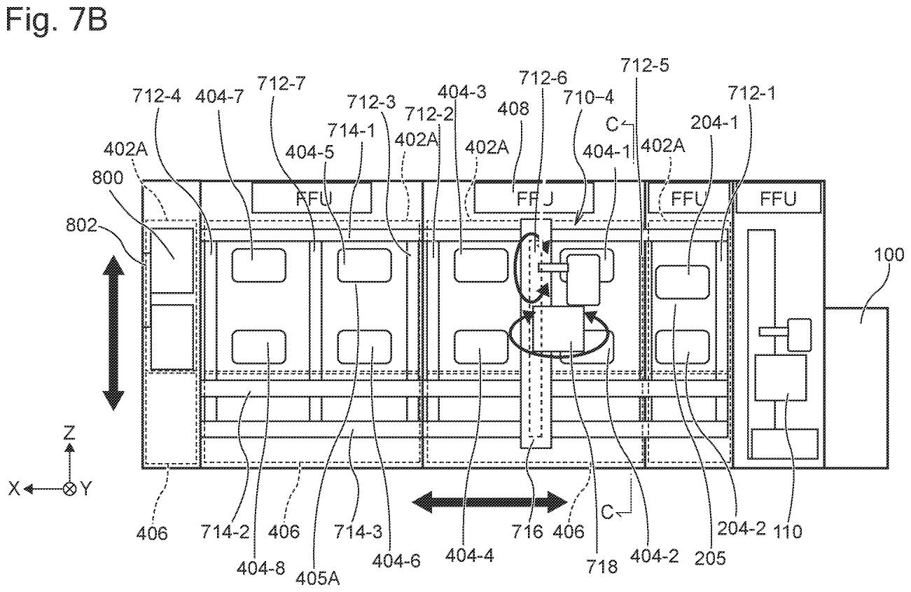

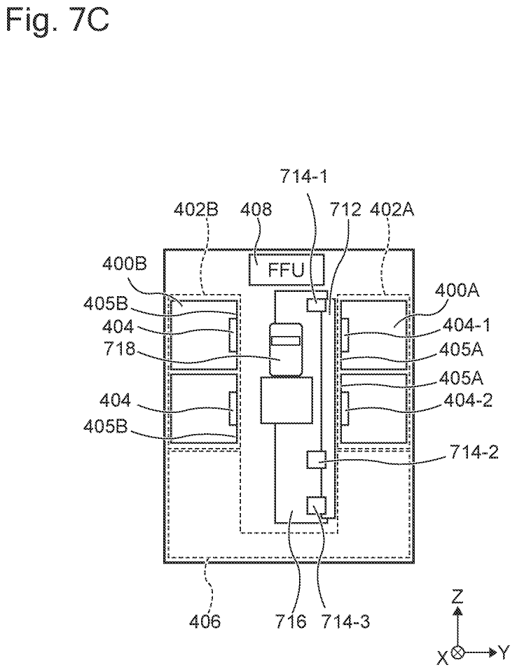

FIG. 7A is a plan view illustrating an overall configuration of a plating apparatus according to one embodiment. FIG. 7B is a cross-sectional view of the B-B line of FIG. 7A. FIG. 7C is a cross-sectional view of the C-C line of FIG. 7B. Since the plating apparatus 1000 illustrated in FIG. 7 is the same as the plating apparatus 1000 illustrated in FIG. 4 except for the attachment member configuration, the same configuration will not be described.

As illustrated in FIG. 7, an attachment member 710-4 includes additional fixed rails 712-5 to 712-7 as compared with the attachment member 710-2 of FIG. 4. Specifically, the fixed rails 712-1, 712-5 are disposed on both sides of the substrate loading/unloading ports 204-1, 204-2 in the X direction. The fixed rails 712-5, 712-6 are disposed on both sides of the substrate loading/unloading ports 404-1, 404-2 in the X direction. The fixed rails 712-6, 712-2 are disposed on both sides of the substrate loading/unloading ports 404-3, 404-4 in the X direction. The fixed rails 712-3, 712-7 are disposed on both sides of the substrate loading/unloading ports 404-5, 404-6 in the X direction. According to this embodiment, since the additional fixed rails 712-5 to 712-7 are provided, the stiffness of the attachment member 710-4 can be further increased, thus ensuring the improved substrate transfer rate by the transfer apparatus 700.

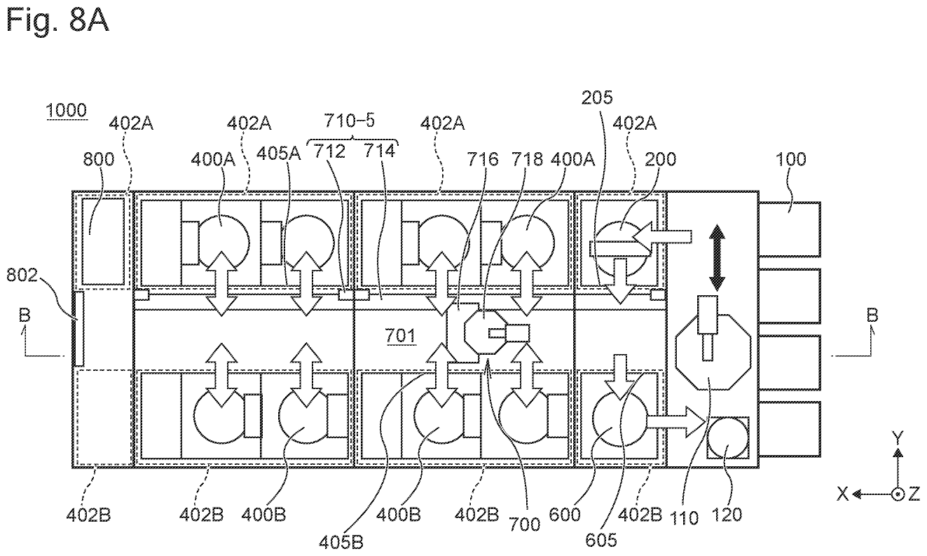

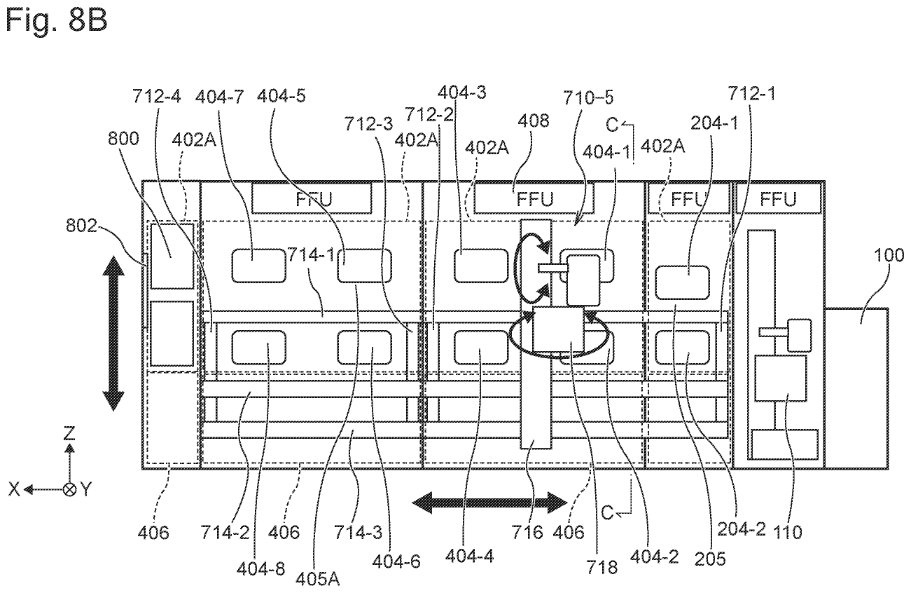

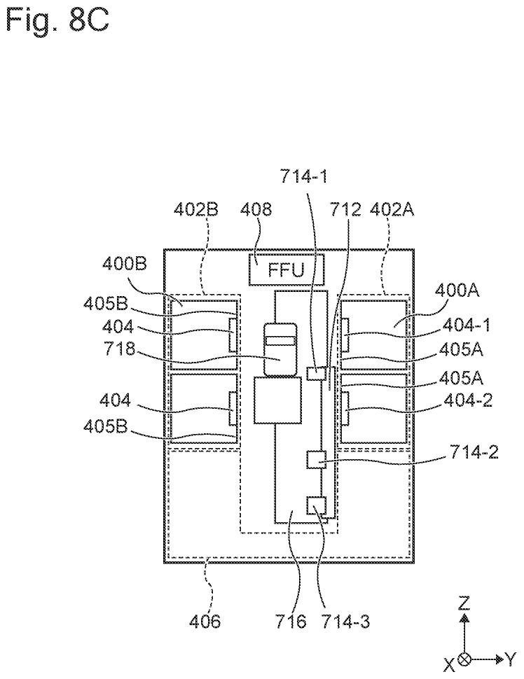

FIG. 8A is a plan view illustrating an overall configuration of a plating apparatus according to one embodiment. FIG. 8B is a cross-sectional view of the B-B line of FIG. 8A. FIG. 8C is a cross-sectional view of the C-C line of FIG. 8B. Since the plating apparatus 1000 illustrated in FIG. 8 is the same as the plating apparatus 1000 illustrated in FIG. 4 except for the attachment member configuration, the same configuration will not be described.

As illustrated in FIG. 8, the attachment member 710-5 is different from the attachment member 710-2 of FIG. 4 in an installation position of the traveling rail 714-1. Specifically, the traveling rails 714-1, 714-2 are disposed on both sides of the substrate loading/unloading ports 204-2 and the substrate loading/unloading ports 404-2, 404-4, 404-6, and 404-8 in the Z direction. According to this embodiment, the stiffness of the attachment member 710-5 can be maintained even when it is difficult to provide the traveling rail 714-1 at the top of the fixed rail 712 due to interference with another component or the like.

While several embodiments of the present invention have been described above, the above-described embodiments of the present invention are intended to facilitate understanding of the present invention and are not intended to limit the present invention. The present invention may be modified and improved without departing from its spirit, and it goes without saying that the present invention includes equivalents of the present invention. To the extent that at least part of the above-described problems can be solved, or at least part of the effect can be achieved, any combination or omission of each component described in the claims and specification is possible.

This application discloses, as one embodiment, a transfer apparatus for transferring a substrate in an elevating direction and a traveling direction perpendicular to the elevating direction. The transfer apparatus includes an attachment member, an elevating rail, and a transfer robot. The attachment member is fixed to a side surface of a module frame for installing a processing module including a substrate loading/unloading port. The attachment member includes a plurality of traveling rails extending in a traveling direction. The plurality of traveling rails are disposed on both sides of the substrate loading/unloading port in the elevating direction. The elevating rail extends in the elevating direction across the plurality of traveling rails and is movable along the plurality of traveling rails. The transfer robot is configured to be movable vertically along the elevating rail and including a hand for holding a substrate.

This application further discloses, as one embodiment, the transfer apparatus in which the attachment member further includes a plurality of fixed rails fixed to the side surface and extending in the elevating direction, the plurality of traveling rails are fixed to the plurality of fixed rails, and the plurality of fixed rails and the plurality of traveling rails are disposed to surround the substrate loading/unloading port.

This application further discloses, as one embodiment, the transfer apparatus in which the plurality of fixed rails and the plurality of traveling rails are disposed to surround a plurality of the substrate loading/unloading ports of a plurality of the processing modules installed in line in at least one direction of the elevating direction and the traveling direction in the module frame.

This application further discloses, as one embodiment, a substrate processing apparatus. The substrate processing apparatus includes a first processing module, a second processing module, a first module frame, a second module frame, a substrate transfer space, and the above-described transfer apparatus. The first processing module has a first side surface on which the substrate loading/unloading port is formed. The second processing module has a second side surface on which the substrate loading/unloading port is formed. The first module frame is for installing the first processing module. The second module frame is for installing the second processing module. The second module frame is spaced apart from the first module frame such that the first side surface and the second side surface face one another. The substrate transfer space is surrounded by the first side surface and the second side surface to be formed. The above-described transfer apparatus disposed in the substrate transfer space and attached to the side surface of the first module frame or the second module frame.

This application further discloses, as one embodiment, the substrate processing apparatus that further include a fan module disposed above the substrate transfer space and configured to provide a gas to the substrate transfer space.

This application further discloses, as one embodiment, the substrate processing apparatus in which the first processing module and the second processing module include a plating module for performing a plating process on the substrate.

This application further discloses, as one embodiment, the substrate processing apparatus in which the first processing module further includes a pre-wet module for performing a pre-wet process on the substrate, and the second processing module further includes a drying module for drying the substrate.

This application further discloses, as one embodiment, the substrate processing apparatus in which in a first area adjacent to the substrate transfer space in the traveling direction of the transfer robot, a dry robot for gripping or releasing of the substrate between a substrate cassette, the pre-wet module, and the drying module is disposed, and in a second area adjacent to the substrate transfer space opposite to the first area in the traveling direction of the transfer robot, an access port for accessing the transfer apparatus disposed in the substrate transfer space from outside the substrate processing apparatus.

### REFERENCE SIGNS LIST

130 . . . first area
200 . . . pre-wet module
204 . . . side surface (substrate loading/unloading port)
204, 404 . . . substrate loading/unloading port
204 . . . substrate loading/unloading port
205 . . . first side surface
400 . . . plating module
402A . . . first module frame
402B . . . second module frame
404 . . . substrate loading/unloading port
405A . . . first side surface
405B, 605 . . . second side surface
408 . . . fan filter device
600 . . . spin rinse dryer
604 . . . substrate loading/unloading port
700 . . . transfer apparatus
701 . . . substrate transfer space
710-1 to 710-5 . . . attachment member
712 . . . fixed rail
714 . . . traveling rail
716 . . . elevating rail
718 . . . transfer robot
802 . . . access port
810 . . . second area
1000 . . . plating apparatus

1. A transfer apparatus for transferring a substrate in an elevating direction and a traveling direction perpendicular to the elevating direction, comprising:
an attachment member fixed to a side surface of a module frame for installing a processing module including a substrate loading/unloading port, the attachment member including a plurality of traveling rails extending in a traveling direction, the plurality of traveling rails being disposed on both sides of the substrate loading/unloading port in the elevating direction;
an elevating rail extending in the elevating direction across the plurality of traveling rails and being movable along the plurality of traveling rails; and
a transfer robot configured to be movable vertically along the elevating rail and including a hand for holding a substrate.

2. The transfer apparatus according to claim 1, wherein
the attachment member further includes a plurality of fixed rails fixed to the side surface and extending in the elevating direction,
the plurality of traveling rails are fixed to the plurality of fixed rails, and
the plurality of fixed rails and the plurality of traveling rails are disposed to surround the substrate loading/unloading port.

3. The transfer apparatus according to claim 2, wherein
the plurality of fixed rails and the plurality of traveling rails are disposed to surround a plurality of the substrate loading/unloading ports of a plurality of the processing modules installed in line in at least one direction of the elevating direction and the traveling direction in the module frame.

4. A substrate processing apparatus comprising:
a first processing module having a first side surface on which the substrate loading/unloading port is formed;
a second processing module having a second side surface on which the substrate loading/unloading port is formed; and
a first module frame for installing the first processing module;
a second module frame for installing the second processing module, the second module being spaced apart from the first module frame such that the first side surface and the second side surface face one another;
a substrate transfer space surrounded by the first side surface and the second side surface to be formed; and
the transfer apparatus according to claim 1 disposed in the substrate transfer space and attached to the side surface of the first module frame or the second module frame.

5. The substrate processing apparatus according to claim 4, further comprising
a fan module disposed above the substrate transfer space and configured to provide a gas to the substrate transfer space.

6. The substrate processing apparatus according to claim 5, wherein
the first processing module and the second processing module include a plating module for performing a plating process on the substrate.

7. The substrate processing apparatus according to claim 6, wherein
the first processing module further includes a pre-wet module for performing a pre-wet process on the substrate, and
the second processing module further includes a drying module for drying the substrate.

8. The substrate processing apparatus according to claim 7, wherein
in a first area adjacent to the substrate transfer space in the traveling direction of the transfer robot, a dry robot for gripping or releasing of the substrate between a substrate cassette, the pre-wet module, and the drying module is disposed, and
in a second area adjacent to the substrate transfer space opposite to the first area in the traveling direction of the transfer robot, an access port for accessing the transfer apparatus disposed in the substrate transfer space from outside the substrate processing apparatus.
